(19) United States
(12) Patent Application Publication
(10) Pub. No.: US 2013/0214389 A1
(43) Pub. Date: Aug. 22, 2013

(54) INTEGRATED CIRCUIT

(71) Applicant: SK HYNIX INC., Gyeonggi-do (KR)

(72) Inventors: Dong-Uk LEE, Gyeonggi-do (KR); Sang-Hoon SHIN, Gyeonggi-do (KR)

(73) Assignee: SK HYNIX INC., Gyeonggi-do (KR)

(21) Appl. No.: 13/716,296

(22) Filed: Dec. 17, 2012

(30) Foreign Application Priority Data
Feb. 17, 2012 (KR) 10-2012-0016444

(51) Int. Cl. H01L 23/538

(52) U.S. Cl. CPC H01L 23/5384
USPC 257/621

(57) ABSTRACT

An integrated circuit includes a first chip having a plurality of through-chip vias, and a second chip stacked on the first chip and having a plurality of through-chip vias which are disposed at positions corresponding to the plurality of through-chip vias of the first chip and each of which is connected with at least one through-chip via of the first chip arranged in an oblique direction, which is not on a straight line extending in a chip stacking direction, among the plurality of through-chip vias of the first chip, wherein the first chip inputs/outputs a signal through a through-chip via which is selected by first repair information among the plurality of through-chip vias of the first chip, and the second chip inputs/outputs a signal through a through-chip via which is selected by second repair information among the plurality of through-chip vias of the second chip.

### CROSS-REFERENCE TO RELATED APPLICATIONS

The present application claims priority of Korean Patent Application No. 10-2012-0016444, filed on Feb. 17, 2012, which is incorporated herein by reference in its entirety.

### BACKGROUND

1. Field

Exemplary embodiments of the present invention relate to an integrated circuit.

2. Description of the Related Art

In order to increase the degree of integration of an integrated circuit, a 3D (three-dimensional) integrated circuit in which a plurality of chips are stacked and packaged has been developed. The 3D integrated circuit may achieve a maximum degree of integration in the same space by vertically stacking at least two chips.

Recently, a through-chip via (e.g., through-silicon via) type package has been used, in which a plurality of stacked chips are electrically connected with one another by through-silicon vias (hereinafter, referred to as TSVs) formed therethrough. In an integrated circuit using TSVs, since chips are connected with one another by TSVs formed to pass therethrough, the area of a package may be efficiently reduced when compared to an integrated circuit in which respective chips are connected with one another by bonding wires.

FIG. 1 is a diagram illustrating a conventional 3D integrated circuit. A case in which four chips are stacked and constitute one integrated circuit will be described with reference to FIG. 1.

Referring to FIG. 1, first to fourth chips C1 to C4 respectively include pluralities of first to fourth TSVs T1 to T16 which are sequentially disposed. The first to fourth chips C1 to C4 are electrically connected through the pluralities of first to fourth TSVs T1 to T16. A plurality of first TSVs T1, T5, T9, and T13 are arranged on a straight line extending in the stacking direction of the first to fourth chips C1 to C4, and electrically connect the first to fourth chips C1 to C4. A plurality of second TSVs T2, T6, T10, and T14 are arranged on a straight line extending in the stacking direction of the first to fourth chips C1 to C4, and electrically connect the first to fourth chips C1 to C4. Similarly, a plurality of third TSVs T3, T7, T11, and T15 and a plurality of fourth TSVs T4, T8, T12, and T16 are arranged on straight lines extending in directions parallel to the stacking direction of the first to fourth chips C1 to C4, and electrically connect the first to fourth chips C1 to C4.

All the TSVs T1 to T16, which are formed through the first to fourth chips C1 to C4, are connected with input/output units IO1 to IO16. As can be seen from FIG. 1, while each of the first to fourth chips C1 to C4 includes four input/output units, one input/output unit among the input/output units included in each of the first to fourth chips C1 to C4 is used to actually input/output a signal. Accordingly, among the four input/output units included in each of the first to fourth chips C1 to C4, the one input/output unit used to actually input/output a signal is activated, and the remaining three input/output units are deactivated.

The plurality of first TSVs T1, T5, T9, and T13 form a communication path CH1 with the first chip C1. The plurality of second TSVs T2, T6, T10, and T14 form a communication path CH2 with the second chip C2. The plurality of third TSVs T3, T7, T11, and T15 form a communication path CH3 with the third chip C3. The plurality of fourth TSVs T4, T8, T12, and T16 form a communication path CH4 with the fourth chip C4. In order for communication of the respective chips C1 to C4, among the input/output units IO1 to IO4, IO5 to IO8, IO9 to IO12, and IO13 to IO16 of the respective chips C1 to C4, the input/output unit IO1 connected with the first TSV T1 of the first chip C1, the input/output unit IO6 connected with the second TSV T6 of the second chip C2, the input/output unit IO11 connected with the third TSV T11 of the third chip C3 and the input/output unit IO16 connected with the fourth TSV T16 of the fourth chip C4 are activated as designated by the reference symbol ON, and the remaining input/output units are deactivated as designated by the reference symbol OFF.

In the conventional integrated circuit, independent communication paths (hereinafter, referred to as ‘channels’) are assigned to the respective stacked semiconductor chips, and each semiconductor chip receives or outputs the signal transferred through a corresponding channel, by one input/output unit. However, since all the semiconductor chips are fabricated through the same processes to have the same configuration, they are just fabricated to include input/output units which are connected with all the TSVs formed in all the semiconductor chips. That is to say, as shown in FIG. 1, the semiconductor chips are fabricated to each include the same number of input/output units as the number of all the TSVs formed in each semiconductor chip, and are configured in such a manner that, after the semiconductor chips are stacked, only one input/output unit is activated in each semiconductor chip to form an individual channel. When the integrated circuit actually operates, the remaining input/output units except the one input/output unit in each semiconductor chip becomes unnecessary circuits, and the areas occupied by these unnecessary circuits adversely influence the integration of the integrated circuit.

Therefore, in order to solve this problem, when connecting TSVs included in respective semiconductor chips, a method has been suggested, in which, instead of connecting TSVs arranged on straight lines extending in directions parallel to the stacking direction of the semiconductor chips, the TSVs are connected in a variety of ways. In this case, when a fail occurs in a TSV, how the failed TSV is to be replaced should be considered.

### SUMMARY

Exemplary embodiments of the present invention are directed to an integrated circuit capable of performing repair when a fail occurs in a through-chip via in a structure in which through-chip vias formed in stacked semiconductor chips are connected in oblique directions (i.e., shift-connected) with through-chip vias of adjoining semiconductor chips.

In accordance with an embodiment of the present invention, an integrated circuit may include a first chip having a plurality of through-chip vias, and a second chip stacked on the first chip and having a plurality of through-chip vias which are disposed at positions corresponding to the plurality of through-chip vias of the first chip and each of which is connected with at least one through-chip via of the first chip arranged in an oblique direction, which is not on a straight line extending in a chip stacking direction, among the plurality of through-chip vias of the first chip, wherein the first chip inputs/outputs a signal through a through-chip via which is selected by first repair information among the plurality of through-chip vias of the first chip, and the second chip inputs/outputs a signal through a through-chip via which is selected by second repair information among the plurality of through-chip vias of the second chip.

In accordance with another embodiment of the present invention, an integrated circuit may include a first chip having first to N-th (N is a natural number) through-chip vias, and a second chip stacked on the first chip and having first to N-th through-chip vias, wherein the K-th (K is a natural number satisfying 1≦K≦N) through-chip via of the first chip and the K-th through-chip via of the second chip are arranged on a straight line extending in a chip stacking direction, the K-th through-chip via of the first chip is connected with at least one through-chip via of the second chip among the first to N-th through-chip vias of the second chip which is not the K-th through-chip via of the second chip, the first chip inputs/outputs a signal through a through-chip via which is selected by first repair information among the first to N-th through-chip vias of the first chip, and the second chip inputs/outputs a signal through a through-chip via which is selected by second repair information among the first to N-th through-chip vias of the second chip.

In accordance with yet another embodiment of the present invention, an integrated circuit may include first to M-th chips stacked upon one after another and each including first to N-th (N is a natural number) through-chip vias, wherein the K-th (K is a natural number satisfying 1≦K≧N) through-chip vias respectively included in the first to M-th chips are arranged on a straight line extending in a stacking direction of the first to M-th chips, the K-th through-chip vias respectively included in the first to M-th chips are connected with one or more through-chip vias among the first to N-th through-chip vias included in the adjacently stacked chip, which are not the K-th through-chip vias, and each of the first to M-th chips inputs/outputs a corresponding signal through through-chip via which are selected by corresponding repair information among the corresponding first to N-th through-chip vias.

### BRIEF DESCRIPTION OF THE DRAWINGS

FIG. 1 is a diagram illustrating a conventional 3D integrated circuit.

FIG. 2 is a diagram illustrating a 3D integrated circuit in which TSVs are shift-connected.

FIG. 3 is a diagram illustrating a 3D integrated circuit in accordance with an embodiment of the present invention.

FIG. 4 is a diagram illustrating a 3D integrated circuit in accordance with another embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like numbered parts in the various figures and embodiments of the present invention.

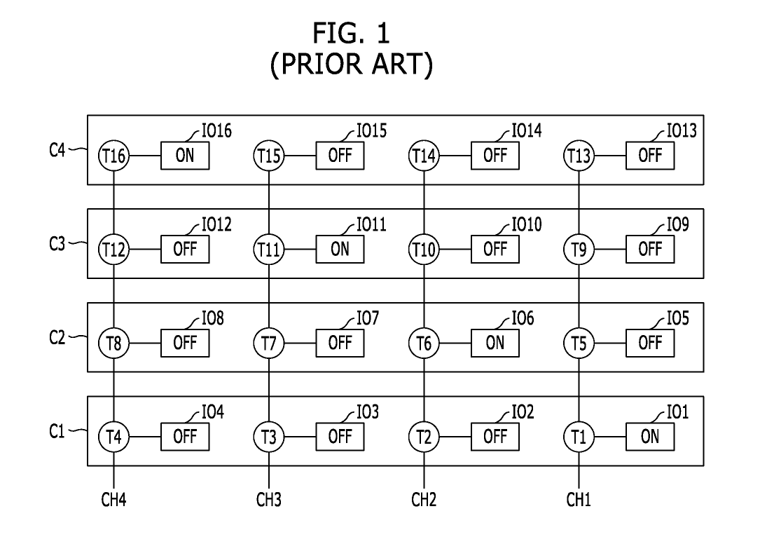

While through-chip vias (e.g., TSVs) are shown to have a circular shape and connection lines for connecting the through-chip vias are shown to have a straight line shape in the following descriptions for the sake of convenience in explanation, those shapes may not be the actual shapes of through-chip vias and connection lines and are only to illustrate the positions of through-chip vias and connection states thereof. Also, through-chip vias positioned in an oblique direction with respect to a certain through-chip via indicate not those through-chip vias which are positioned in a chip stacking direction but those through-chip vias which are present at different positions, among through-chip vias formed in adjoining chips. For example, when viewed from the position of the TSV T7 of the second chip C2 in FIG. 1, the TSVs T1, T2, and T4 of the first chip C1 except the TSV T3 and the TSVs T9, T10 and T12 of the third chip C3 except the TSV T11 may correspond to the TSVs positioned in an oblique direction with respect to the TSV T7.

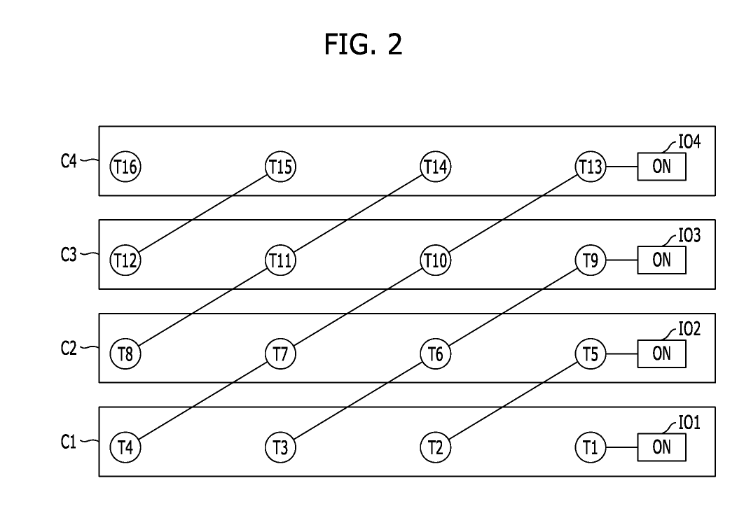

FIG. 2 is a diagram illustrating a 3D integrated circuit in which TSVs are shift-connected.

Referring to FIG. 2, first to fourth chips C1 to C4 respectively include pluralities of first to fourth TSVs T1 to T16 which are sequentially disposed, and perform communication through channels CH1 to CH4 which are formed by connecting TSVs. Unlike the integrated circuit shown in FIG. 1, in the integrated circuit of FIG. 2, the pluralities of TSVs T1 to T16 form the channels CH1 to CH4 by being connected with TSVs which are not TSVs positioned on straight lines extending in directions parallel to the stacking direction of the first to fourth chips C1 to C4. FIG. 2 shows the case where respective TSVs are connected with TSVs which adjoin the TSVs positioned on the straight lines extending in the directions parallel to the stacking direction of the first to fourth chips C1 to C4.

In detail, the fourth TSV T4 of the first chip C1, the third TSV T7 of the second chip C2, the second TSV T10 of the third chip C3 and the first TSV T13 of the fourth chip C4 are electrically connected and form the channel CH4 for communication of the fourth chip C4. The third TSV T3 of the first chip C1, the second TSV T6 of the second chip C2 and the first TSV T9 of the third chip C3 are electrically connected and form the channel CH3 for communication of the third chip C3. The second TSV T2 of the first chip C1 and the first TSV T5 of the second chip C2 are electrically connected and form the channel CH2 for communication of the second chip C2. The first TSV T1 of the first chip C1 forms the channel CH1 for communication of the first chip C1.

By connecting TSVs positioned in a diagonal direction in this way, all the first to fourth chips C1 to C4 included in the integrated circuit of FIG. 2 may input/output signals through the first TSVs T1, T5, T9, and T13 which are positioned in a straight line extending in the stacking direction of the first to fourth chips C1 to C4. Accordingly, input/output unit IO1 to IO4 for inputting/outputting signals to and from the first to fourth chips C1 to C4 are respectively connected to the first TSVs T1, T5, T9, and T13 which are included in the respective first to fourth chips C1 to C4. If the integrated circuit has the structure shown in FIG. 2, all the first to fourth chips C1 to C4 may be fabricated to have the same structure with only one input/output unit.

Hereinbelow, repair in the case where a fail occurs in a TSV or in a connection between TSVs in the integrated circuit of FIG. 2 will be described.

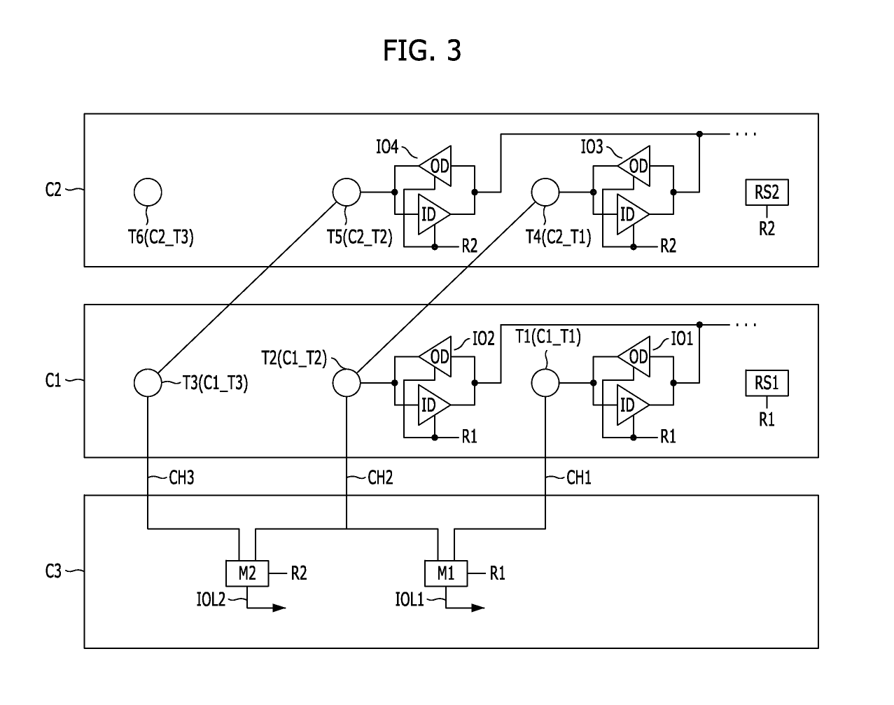

FIG. 3 is a diagram illustrating a 3D integrated circuit in accordance with an embodiment of the present invention.

Referring to FIG. 3, the integrated circuit includes a first chip C1 including a plurality of TSVs T1 to T3, and a second chip C2 stacked on the first chip C1 and including a plurality of TSVs T4 to T6 which are disposed at positions corresponding to the plurality of TSVs T1 to T3 of the first chip C1 and are connected with one or more of the plurality of TSVs T1 to T3 of the first chip C1 positioned in oblique directions. The first chip C1 inputs/outputs a signal through a TSV which is selected by first repair information R1 among the plurality of TSVs T1 to T3 of the first chip C1, and the second chip C2 inputs/outputs a signal through a TSV which is selected by second repair information R2 among the plurality of TSVs T4 to T6 of the second chip C2. The integrated circuit further includes a third chip C3 which is disposed in a direction opposite to the stacking direction of the second chip C2 when viewed from the position of the first chip C1. The third chip C3 includes a first input/output line IOL1 which transfers a signal to be inputted/outputted between an outside (an outside of the integrated circuit) and the first chip C1, a second input/output line IOL2 which transfers a signal to be inputted/outputted between the outside and the second chip C2, a first transfer unit M1 which transfers a signal between the TSV of the first chip C1 selected by the first repair information R1 and the first input/output line IOL1, and a second transfer unit M2 which transfers a signal between the TSV of the first chip C1 selected by the second repair information R2 and the second input/output line IOL2. The TSV of the first chip C1 selected by the second repair information R2 is connected with the TSV of the second chip C2 selected by the second repair information R2.

FIG. 3 shows the integrated circuit in which the third chip C3, the first chip C1 and the second chip C2 are stacked in that sequence. The third chip C3 corresponds to a chip (a master chip) which takes charge of communication and interfacing between the integrated circuit and the outside, and the first chip C1 and the second chip C2 correspond to chips (slave chips) which process signals applied from the outside, according to an inherent function of the integrated circuit (for example, a data input/output function in the case of a memory device). While FIG. 3 shows that the third chip C3 as a master chip takes charge of communication between the integrated circuit and the outside, it is to be noted that the third chip C3 may perform both an inherent operation of the integrated circuit and communication with the outside according to a design. Furthermore, a chip stacking sequence may be changed according to a design.

Among a plurality of TSVs T1 to T3 of the first chip C1 and a plurality of TSVs T4 to T6 of the second chip C2, TSVs of the first chip C1 and TSVs of the second chip C2 which are disposed at corresponding positions are arranged on straight lines extending in directions parallel to the stacking direction of the second chip C2. That is to say, as can be seen from FIG. 3, the TSVs T1 and T4, the TSVs T2 and T5 and the TSVs T3 and T6 are arranged on straight lines. However, the respective TSVs are connected with other TSVs which are not arranged on the same straight lines as them, extending in the directions parallel to the stacking direction of the second chip C2. FIG. 3 shows that the TSVs T2 and T4 are connected with each other and the TSVs T3 and T5 are connected with each other. The TSV T1 forms a first channel CH1, the TSVs T2 and T4 form a second channel CH2, and the TSVs T3 and T5 form a third channel CH3.

Hereafter, the integrated circuit will be described with reference to FIG. 3.

The first chip C1 includes the plurality of TSVs T1 to T3 and inputs/outputs a signal through one of the plurality of TSVs T1 to T3. In detail, the signal of the first chip C1 is inputted/outputted through the TSV T1 which is disposed at a first position, among the plurality of TSVs T1 to T3 of the first chip C1. If a fail occurs in the channel CH1 including the TSV T1 disposed at the first position, the signal of the first chip C1 is inputted/outputted through another TSV other than the TSV T1 of the first position. In FIG. 3, it is shown that, if a fail occurs in the channel CH1 including the TSV T1, the signal of the first chip C1 is inputted/outputted through the TSV T2. In other words, if the signal of the first chip C1 cannot be transferred through the first channel CH1, the signal of the first chip C1 is transferred through the second channel CH2. For reference, the occurrence of a fail in the channel CH1 including the TSV T1 means that a fail occurs in the TSV T1 itself or another component element connected with the TSV T1 (for example, another TSV or a wiring line connecting TSVs), so the signal of the first chip C1 cannot be inputted/outputted through the channel CH1 including the TSV T1.

For such an operation, the first chip C1 includes one or more input/output units IO1 and IO2 for inputting/outputting a signal. One or more TSVs among the plurality of TSVs T1 to T3 of the first chip C1 are respectively connected to the input/output units IO1 and IO2 for inputting/outputting the signal of the first chip C1 (FIG. 3 shows that the TSVs T1 and T2 are respectively connected to the input/output units IO1 and IO2). Each of the input/output units IO1 and IO2 may be a driver for driving a signal to be outputted from the first chip C1 or a signal to be inputted to the first chip C1, and includes an input driver ID and an output driver OD. The input/output units IO1 and IO2 are activated or deactivated in response to the first repair information R1, and the signal of the first chip C1 is driven through the input/output unit activated between the input/output units IO1 and IO2.

Namely, while the signal of the first chip C1 is basically inputted/outputted through the TSV T1, it is inputted/outputted through the TSV T2 in the case where a fail occurs in the TSV T1. Thus, in the case where no fail occurs in the TSV T1, the input/output unit IO1 is activated and the input/output unit IO2 is deactivated by the first repair information R1. Conversely, in the case where a fail occurs in the TSV T1, the input/output unit IO1 is deactivated and the input/output unit IO2 is activated by the first repair information R1. For reference, the first repair information R1 may be stored in a first information storage unit RS1 included in the first chip C1. The first information storage unit RS1 may include at least one fuse circuit which is determined as to whether to be cut or not, according to the first repair information R1.

Here, a range for selecting a TSV through which the signal of a chip is to be inputted/outputted is determined according to the number of TSVs to which input/output units are connected, among the entire TSVs of the chip. Since FIG. 3 shows that input/output units are connected to two TSVs among the TSVs of each chip, a TSV through which the signal of the chip is to be inputted/outputted may be determined as one of the two TSVs. The number of TSVs to which input/output units are connected may be changed according to a design. As the number of TSVs to which input/output units are connected increases, the flexibility of a repair operation may be enhanced.

The second chip C2 includes the plurality of TSVs T4 to T6 and inputs/outputs a signal through one of the plurality of TSVs T4 to T6. In detail, the signal of the second chip C2 is inputted/outputted through the TSV T4 which is formed at a first position, among the plurality of TSVs T4 to T6 of the second chip C2. If a fail occurs in the channel CH2 including the TSV T4 disposed at the first position, the signal of the second chip C2 is inputted/outputted through another TSV other than the TSV T4 of the first position. In FIG. 3, it is shown that, if a fail occurs in the channel CH2 including the TSV T4, the signal of the second chip C2 is inputted/outputted through the TSV T5. In other words, if the signal of the second chip C2 cannot be transferred through the second channel CH2, the signal of the second chip C2 is transferred through the third channel CH3. For reference, the occurrence of a fail in the channel CH2 including the TSV T4 means that a fail occurs in the TSV T4 itself or another component element connected with the TSV T4 (for example, another TSV (the TSV T2) or a wiring line connecting TSVs (a wiring line connecting the TSVs T4 and T2)), so the signal of the second chip C2 cannot be inputted/outputted through the channel CH2 including the TSV T4. The first position of the first chip C1 and the first position of the second chip C2 are arranged on the straight line extending in the stacking direction of the second chip C2.

In the case of the second chip C2, although a fail does not occur in the TSV T4 of the first position, if a fail occurs in the channel CH1 including the TSV T1 of the first chip C1 which is disposed at the first position, the signal of the second chip C2 is inputted/outputted through another TSV other than the TSV T4 of the first position. The reason to this is as follows.

As described above, if a fail occurs in the channel CH1 including the TSV T1 of the first chip C1, the signal of the first chip C1 is inputted/outputted through the TSV T2. That is to say, the signal of the first chip C1 is transferred through the second channel CH2. Because the communication paths of the first chip C1 and the second chip C2 should not overlap with each other, if the signal of the first chip C1 is inputted/outputted through the TSV T2 (the second channel CH2), the signal of the second chip C2 cannot be inputted/outputted through the TSV T4 which is connected with the TSV T2 (that is, the signal of the second chip C2 cannot be transferred through the second channel CH2). Accordingly, in the case where a fail occurs in the channel CH1 including the TSV T1 in the first chip C1, the signal of the second chip C2 is inputted/outputted through the TSV T5.

For such an operation, the second chip C2 includes one or more input/output units IO3 and IO4 for inputting/outputting a signal, One or more TSVs among the plurality of TSVs T4 to T6 of the second chip C2 are respectively connected to the input/output units IO3 and IO4 for inputting/outputting the signal of the second chip C2 (FIG. 3 shows that the TSVs T4 and T5 are respectively connected to the input/output units IO3 and IO4). Each of the input/output units IO3 and IO4 may be a driver for driving a signal to be outputted from the second chip C2 or a signal to be inputted to the second chip C2, and includes an input driver ID and an output driver OD. The input/output units IO3 and IO4 are activated or deactivated in response to the second repair information R2, and the signal of the second chip C2 is driven through the input/output unit activated between the input/output units IO3 and IO4. The TSVs T1 and T2 of the first chip C1 to which the input/output units IO1 and IO2 of the first chip C1 are connected and the TSVs T4 and T5 of the second chip C2 to which the input/output units IO3 and IO4 of the second chip C2 are connected are arranged on the straight lines extending in the directions parallel to the stacking direction of the second chip C2.

Namely, while the signal of the second chip C2 is basically inputted/outputted through the TSV T4, it is inputted/outputted through the TSV T5 in the case where a fail occurs in the TSV T4 or in the channel CH2 including the TSV T2. Thus, in the case where no fail occurs in the channel CH2 including the TSV T4 and the channel CH1 including the TSV T1, the input/output unit IO3 is activated and the input/output unit IO4 is deactivated by the second repair information R2. Conversely, in the case where a fail occurs in any one of the channel CH2 including the TSV T4 and the channel CH1 including the TSV T1, the input/output unit IO3 is deactivated and the input/output unit IO4 is activated by the second repair information R2. For reference, the second repair information R2 may be stored in a second information storage unit RS2 included in the second chip C2. The second information storage unit RS2 may include at least one fuse circuit which is determined as to whether to be cut or not, according to the second repair information R2.

The repair information R1 and R2 is determined through a test. The first repair information R1 is determined according to whether a channel including a TSV of the first chip has failed or not, and the second repair information R2 is determined according to whether a channel including a TSV of the first chip has failed or not and whether a channel including a TSV of the second chip has failed or not.

The third chip C3 includes a first input/output line IOL1, a second input/output line IOL2, a first transfer unit M1 and a second transfer unit M2 in order to perform communication (or interfacing) between the outside of the integrated circuit and the first and second chips C1 and C2.

The first input/output line IOL1 and the first transfer unit M1 are component elements for communication of the first chip C1. A TSV to and from which the signal of the first chip C1 is to be inputted/outputted is selected between the TSVs T1 and T2 of the first chip C1 by the first transfer unit M1 in response to the first repair information R1. Accordingly, the first transfer unit M1 connects the TSV between the TSVs T1 and T2 of the first chip C1 to and from which the signal of the first chip C1 is to be inputted/outputted and the first input/output line IOL1 with each other in response to the first repair information R1.

For example, in the case where the signal of the first chip C1 is inputted/outputted through the TSV T1, the TSV T1 and the first input/output line IOL1 are connected, and in the case where the signal of the first chip C1 is inputted/outputted through the TSV T2, the TSV T2 and the first input/output line IOL1 are connected. Since the TSV to and from which the signal of the first chip C1 is to be inputted/outputted is determined by the first repair information R1, the first transfer unit M1 connects the TSV of the first chip C1 which is determined in response to the first repair information R1, with the first input/output line IOL1.

The second input/output line IOL2 and the second transfer unit M2 are component elements for communication of the second chip C2. A TSV between the TSVs T2 and T3 of the first chip C1 which is connected with a TSV of the second chip C2 to and from which the signal of the second chip C2 is to be inputted/outputted is selected by the second transfer unit M2 in response to the second repair information R2. Accordingly, the second transfer unit M2 connects the TSV between the TSVs T2 and T3 of the first chip C1 which is connected with the TSV of the second chip C2 to and from which the signal of the second chip C2 is to be inputted/outputted and the second input/output line IOL2 with each other in response to the second repair information R2.

For example, in the case where the signal of the second chip C2 is inputted/outputted through the TSV T4, the TSV T2 connected with the TSV T4 and the second input/output line IOL2 are connected, and in the case where the signal of the second chip C2 is inputted/outputted through the TSV T5, the TSV T3 connected with the TSV T5 and the second input/output line IOL2 are connected. Since the TSV to and from which the signal of the second chip C2 is to be inputted/outputted is determined by the second repair information R2, the second transfer unit M2 connects the TSV of the first chip C1 which is determined in response to the second repair information R2, with the second input/output line IOL2.

In the integrated circuit in accordance with the embodiment of the present invention, TSVs included in respective chips are connected in diagonal directions to produce communication paths of the respective chips. In the case where a fail occurs in a TSV, a signal is inputted/outputted through another TSV included in the same chip so as to prevent the entire integrated circuit from becoming useless due to the fail of the TSV.

An integrated circuit in accordance with another embodiment of the present invention will be described with reference back to FIG. 3.

Referring to FIG. 3, an integrated circuit in accordance with the present embodiment includes a first chip C1 including first to N-th TSVs C1_T1 to C1_TN (FIG. 3 shows that N is 3), and a second chip C2 stacked on the first chip C1 and including first to N-th TSVs C2_T1 to C2_T3. The K-th TSV C1_TK of the first chip C1 and the K-th TSV C2_TK of the second chip C2 are arranged on a straight line extending in the stacking direction of the second chip C2. The K-th TSV C1_TK of the first chip C1 is connected with at least one TSV of the first to N-th TSVs C2_T1 to C2_T3 of the second chip C2 which is not the K-th TSV C2_TK. The first chip C1 inputs and outputs a signal through a TSV which is selected by first repair information R1 among the first to N-th TSVs C1_T1 to C1_T3 of the first chip C1, and the second chip C2 inputs and outputs a signal through a TSV which is selected by second repair information R2 among the first to N-th TSVs C2_T1 to C2_T3 of the second chip C2. The integrated circuit further includes a third chip C3 which is disposed in a direction opposite to the stacking direction of the second chip C2 when viewed from the position of the first chip C1. The third chip C3 includes a first input/output line IOL1 which transfers a signal to be inputted/outputted between an outside (an outside of the integrated circuit) and the first chip C1, a second input/output line IOL2 which transfers a signal to be inputted/outputted between the outside and the second chip C2, a first transfer unit M1 which transfers a signal between the TSV of the first chip C1 selected by the first repair information R1 among the first to N-th TSVs C1_T1 to C1_T3 of the first chip C1 and the first input/output line IOL1, and a second transfer unit M2 which transfers a signal between the TSV of the first chip C1 selected by the second repair information R2 among the first to N-th TSVs C1_T1 to C1_T3 of the first chip C1 and the second input/output line IOL2. The TSV of the first chip C1 selected by the second repair information R2 among the first to N-th TSVs C1_T1 to C1_T3 of the first chip C1 is connected with a TSV of the second chip C2 selected by the second repair information R2 among the first to N-th TSVs C2_T1 to C2_T3 of the second chip C2.

Descriptions for the first to third chips C1 to C3 are the same as those given above with reference to FIG. 3.

In FIG. 3, the K-th TSV C1_TK of the first chip C1 is connected with the K−1-th TSV C2_TK−1 of the second chip C2 (the first TSV C1_T1 of the first chip C1 is connected with no TSV of the second chip C2). The K-th TSV C1_TK of the first chip C1 and the K−1-th TSV C2_TK−1 of the second chip C2 form a K-th channel CHK (the first TSV C1_T1 of the first chip C1 forms a first channel CH1).

The first chip C1 includes the first to N-th TSVs C1_T1 to C1_T3 therein and inputs/outputs a signal through the L-th TSV C1_T1 (FIG. 3 shows that L is 1) among the first to N-th TSVs C1_T1 to C1_T3. In detail, the signal of the first chip C1 is inputted/outputted through the L-th TSV C1_T1 among the first to N-th TSVs C1_T1 to C1_T3 of the first chip C1. If a fail occurs in the channel CH1 including the L-th TSV C1_T1, the signal of the first chip C1 is inputted/outputted through another TSV other than the L-th TSV C1_T1. In FIG. 3, it is shown that, if a fail occurs in the channel CH1 including the first TSV C1_T1, the signal of the first chip C1 is inputted/outputted through the second TSV C1_T2. In other words, if the signal of the first chip C1 cannot be transferred through the first channel CH1, the signal of the first chip C1 is transferred through a second channel CH2. Descriptions for a fail occurred in a TSV are the same as those given above with reference to FIG. 3.

For such an operation, the first chip C1 includes one or more input/output units IO1 and IO2. Among the first to N-th TSVs C1_T1 to C1_T3 of the first chip C1, one or more TSVs including the L-th TSV C1_T1 are respectively connected to the input/output units IO1 and IO2 for inputting/outputting a signal. FIG. 3 shows the case in which the first TSV C1_T1 and the second TSV C1_T2 are respectively connected to the input/output units IO1 and IO2. Descriptions for the input/output units IO1 and IO2 are the same as those given above with reference to FIG. 3.

Namely, in FIG. 3, while the signal of the first chip C1 is basically inputted/outputted through the first TSV C1_T1, it is inputted/outputted through the second TSV C1_T2 in the case where a fail occurs in the channel CH1 including the first TSV C1_T1. Thus, in the case where no fail occurs in the channel CH1 including the first TSV C1_T1, the input/output unit IO1 is activated and the input/output unit IO2 is deactivated by the first repair information R1. Conversely, in the case where a fail occurs in the channel CH1 including the first TSV C1_T1, the input/output unit IO1 is deactivated and the input/output unit IO2 is activated by the first repair information R1.

Here, a range for selecting a TSV through which the signal of a chip is to be inputted/outputted is determined according to the number of TSVs to which input/output units are connected, among the entire TSVs of the chip. Since FIG. 3 shows that input/output units are connected to two TSVs among the TSVs of each chip, a TSV through which the signal of the chip is to be inputted/outputted may be determined as one of the two TSVs. The number of TSVs to which input/output units are connected may be changed according to a design. As the number of TSVs to which input/output units are connected increases, the flexibility of a repair operation may be enhanced.

The second chip C2 includes the first to N-th TSVs C2_T1 to C2_T3 therein and inputs/outputs a signal through the L-th TSV C2_T1 (FIG. 3 shows that L is 1) among the first to N-th TSVs C2_T1 to C2_T3. In detail, the signal of the second chip C2 is inputted/outputted through the L-th TSV C2_T1 among the first to N-th TSVs C2_T1 to C2_T3 of the second chip C2. If a fail occurs in the channel CH2 including the L-th TSV C2_T1, the signal of the second chip C2 is inputted/outputted through another TSV other than the L-th TSV C2_T1. In FIG. 3, it is shown that, if a fail occurs in the channel CH2 including the first TSV C2_T1, the signal of the second chip C2 is inputted/outputted through the second TSV C2_T2. In other words, if the signal of the second chip C2 cannot be transferred through the second channel CH2, the signal of the second chip C2 is transferred through a third channel CH3. Descriptions for a fail occurred in a TSV are the same as those given above with reference to FIG. 3.

In the case of the second chip C2, although a fail does not occur in the channel CH2 including the L-th TSV C2_T1, if a fail occurs in the channel CH1 including the L-th TSV C1_T1 of the first chip C1, the signal of the second chip C2 is inputted/outputted through another TSV other than the L-th TSV C2_T1. The reason to this is the same as that given above with reference to FIG. 3.

For such an operation, the second chip C2 includes one or more input/output units IO3 and IO4. Among the first to N-th TSVs C2_T1 to C2_T3 of the second chip C2, one or more TSVs including the L-th TSV C2_T1 are respectively connected to the input/output units IO3 and IO3 for inputting/outputting a signal. FIG. 3 shows the case in which the first TSV C2_T1 and the second TSV C2_T2 are respectively connected to the input/output units IO3 and IO4. Descriptions for the input/output units IO3 and IO4 are the same as those given above with reference to FIG. 3.

Namely, in FIG. 3, while the signal of the second chip C2 is basically inputted/outputted through the first TSV C2_T1, it is inputted/outputted through the second TSV C2_T2 in the case where a fail occurs in the channel CH2 including the first TSV C2_T1. Thus, in the case where no fail occurs in the channel CH2 including the first TSV C2_T1 of the second chip C2 and the channel CH1 including the first TSV C1_T1 of the first chip C1, the input/output unit IO3 is activated and the input/output unit IO4 is deactivated by the second repair information R2. Conversely, in the case where a fail occurs in any one of the channel CH2 including the first TSV C2_T1 of the second chip C2 and the channel CH1 including the first TSV C1_T1 of the first chip C1, the input/output unit IO3 is deactivated and the input/output unit IO4 is activated by the second repair information R2.

The repair information R1 and R2 is determined through a test. The first repair information R1 is determined according to whether a channel including a TSV of the first chip has failed or not, and the second repair information R2 is determined according to whether a channel including a TSV of the first chip has failed or not and whether a channel including a TSV of the second chip has failed or not.

The third chip C3 includes a first input/output line IOL1, a second input/output line IOL2, a first transfer unit M1 and a second transfer unit M2 in order to perform communication (or interfacing) between the outside of the integrated circuit and the first and second chips C1 and C2.

The first input/output line IOL1 and the first transfer unit M1 are component elements for communication of the first chip C1, A TSV to and from which the signal of the first chip C1 is to be inputted/outputted is selected between the TSVs C1_T1 and C1_T2 of the first chip C1 by the first transfer unit M1 in response to the first repair information R1. Accordingly, the first transfer unit M1 connects the TSV between the TSVs C1_T1 and C1_T2 of the first chip C1 to and from which the signal of the first chip C1 is to be inputted/outputted and the first input/output line IOL1 with each other in response to the first repair information R1.

For example, in the case where the signal of the first chip C1 is inputted/outputted through the first TSV C1_T1, the first TSV C1_T1 and the first input/output line IOL1 are connected, and in the case where the signal of the first chip C1 is inputted/outputted through the second TSV C1_T2, the second TSV C1_T2 and the first input/output line IOL1 are connected. Since the TSV to and from which the signal of the first chip C1 is to be inputted/outputted is determined by the first repair information R1, the first transfer unit M1 connects the TSV of the first chip C1 which is determined in response to the first repair information R1, with the first input/output line IOL1.

The second input/output line IOL2 and the second transfer unit M2 are component elements for communication of the second chip C2, A TSV between the TSVs C1_T2 and C1_T3 of the first chip C1 which is connected with a TSV of the second chip C2 to and from which the signal of the second chip C2 is to be inputted/outputted is selected by the second transfer unit M2 in response to the second repair information R2. Accordingly, the second transfer unit M2 connects the TSV between the TSVs C1_T2 and C1_T3 of the first chip C1 which is connected with a TSV of the second chip C2 to and from which the signal of the second chip C2 is to be inputted/outputted and the second input/output line IOL2 with each other in response to the second repair information R2.

For example, in the case where the signal of the second chip C2 is inputted/outputted through the first TSV C2_T1, the second TSV C1_T2 of the first chip C1 connected with the first TSV C2_T1 of the second chip C2 and the second input/output line IOL2 are connected, and in the case where the signal of the second chip C2 is inputted/outputted through the second TSV C2_T2, the third TSV C1_T3 of the first chip C1 connected with the second TSV C1_T2 of the second chip C2 and the second input/output line IOL2 are connected. Since the TSV to and from which the signal of the second chip C2 is to be inputted/outputted is determined by the second repair information R2, the second transfer unit M2 connects the TSV of the first chip C1 which is determined in response to the second repair information R2, with the second input/output line IOL2.

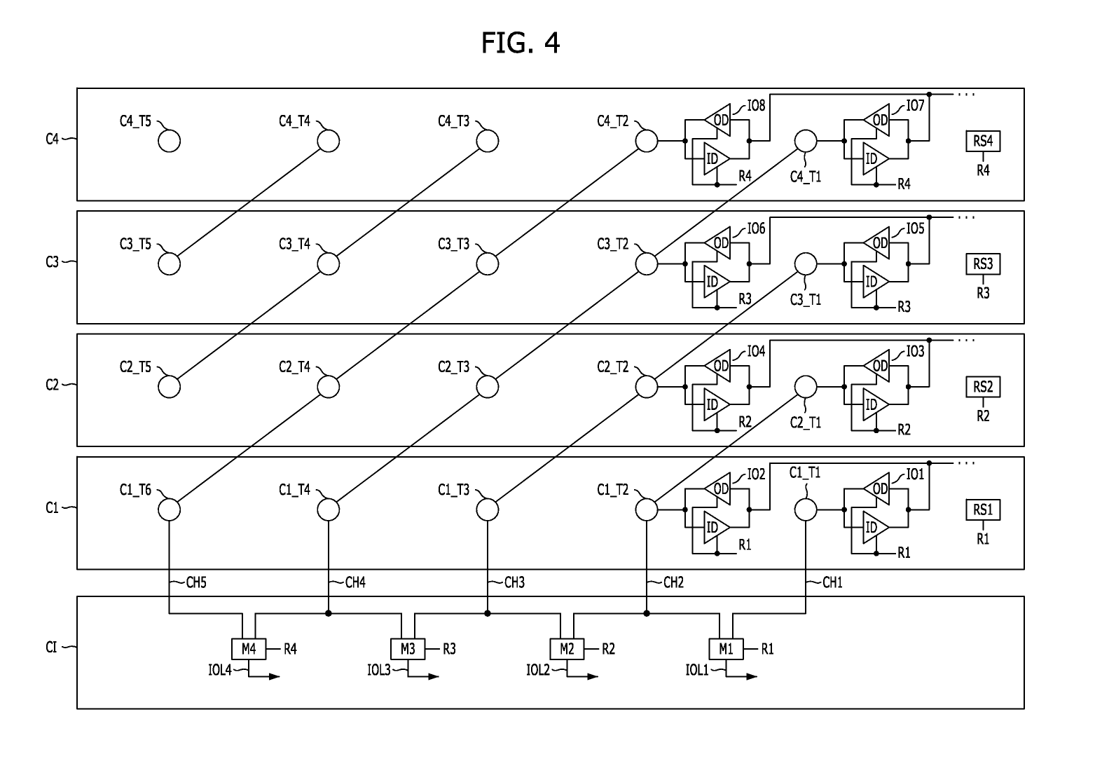

FIG. 4 is a diagram illustrating a 3D integrated circuit in accordance with another embodiment of the present invention. The integrated circuit of FIG. 4 shows a generalized type of the integrated circuit of FIG. 2.

Referring to FIG. 4, the integrated circuit includes first to M-th chips C1 to C4 (FIG. 4 shows that M is 4) which are stacked and include first to N-th TSVs C1_T1 to C1_T5, C2_T1 to C2_T5, C3_T1 to C3_T5, and C4_T1 to C4_T5 (FIG. 4 shows that N is 5), The K-th TSVs C1_TK to C4_TK respectively included in the first to M-th chips C1 to C4 are arranged on a straight line extending in the stacking direction of the first to M-th chips C1 to C4. The K-th TSVs C1_TK to C4_TK respectively included in the first to M-th chips C1 to C4 are connected with one or more TSVs of the first to N-th TSVs C1_T1 to C1_T5, C2_T1 to C2_T5, C3_T1 to C3_T5, and C4_T1 to C4_T5 included in the adjacently stacked first to M-th chips C1 to C4, which are not the K-th TSVs C1_TK to C4_TK. The first to M-th chips C1 to C4 input/output signals through TSVs which are selected by repair information therefor among the first to N-th TSVs C1_T1 to C1_T5, C2_T1 to C2_T5, C3_T1 to C3_T5, and C4_T1 to C4_T5. The integrated circuit further includes an interface chip CI which is disposed in a direction opposite to the stacking direction of the second to M-th chips C2 to C4 when viewed from the position of the first chip C1. The interface chip CI includes first to M-th input/output lines IOL1 to IOL4 which transfer signals to be inputted/outputted between the first to M-th chips C1 to C4 and an outside, and first to M-th transfer units M1 to M4 which transfer signals between the TSVs of the first chip C1 selected by the repair information corresponding to them among the first to N-th TSVs C1_T1 to C1_T4 of the first chip C1 and the first to M-th input/output lines IOL1 to IOL4 corresponding to them.

FIG. 4 shows the integrated circuit in which the interface chip CI and the first to M-th chips C1 to C4 are stacked in that sequence. The interface chip CI corresponds to a chip which takes charge of communication between the integrated circuit and the outside, and the first to M-th chips C1 to C4 correspond to chips (slave chips) which process signals applied from the outside, according to an inherent function of the integrated circuit (for example, a data input/output function in the case of a memory device). While FIG. 4 shows that the interface chip CI as a master chip takes charge of communication between the integrated circuit and the outside, it is to be noted that the interface chip CI may perform both an inherent function of the integrated circuit and communication with the outside according to a design. Furthermore, a chip stacking sequence may be changed according to a design, and the interface chip CI may be stacked uppermost unlike FIG. 4.

Among the first to fifth TSVs C1_T1 to C1_T5, C2_T1 to C2_T5, C3_T1 to C3_T5, and C4_T1 to C4_T5 of the first to fourth chips C1 to C4, the TSVs C1_TK to C4_TK with the same sequential position are arranged on the straight line extending in the stacking direction of the first to fourth chips C1 to C4. That is to say, as can be seen from FIG. 4, the first TSVs C1_T1 to C4_T1 of the first to fourth chips C1 to C4, the second TSVs C1_T2 to C4_T2 of the first to fourth chips C1 to C4, the third TSVs C1_T3 to C4_T3 of the first to fourth chips C1 to C4, the fourth TSVs C1_T4 to C4_T4 of the first to fourth chips C1 to C4, and the fifth TSVs C1_T5 to C4_T5 of the first to fourth chips C1 to C4 are arranged on straight lines extending in directions parallel to the stacking direction of the first to fourth chips C1 to C4.

However, the respective TSVs are connected with other TSVs which are not arranged on the same straight lines as them, extending in the directions parallel to the stacking direction of the first to fourth chips C1 to C4. FIG. 4 shows that a B-th TSV CA_TB of an A-th chip CA is connected with a B+1-th TSV CA−1_TB+1 of an A−1-th chip CA−1 and a B−1-th TSV CA+1 TB−1 of an A+1-th chip CA+1 to form each of first to fifth channels CH1 to CH5 for communication of the first to fourth chips C1 to C4. Therefore, the TSV C1_T1 forms the first channel CH1, and the TSVs C1_T2 and C2_T1 form the second channel CH2. The TSVs C1_T3, C2_T2, and C3_T1 form the third channel CH3. The TSVs C1_T4, C2_T3, C3_T2, and C4_T1 form the fourth channel CH4. The TSVs C1_T5, C2_T4, C3_T3, and C4_T2 form the fifth channel CH5.

Hereafter, the integrated circuit will be described with reference to FIG. 4.

The first chip C1 includes the first to fifth TSVs C1_T1 to C1_T5 and inputs/outputs a signal through an L-th TSV C1_T1 (FIG. 4 shows that L is 1) of the first to fifth TSVs C1_T1 to C1_T5. In detail, the signal of the first chip C1 is inputted/outputted through the first TSV C1_T1. If a fail occurs in the channel CH1 including the first TSV C1_T1, the signal of the first chip C1 is inputted/outputted not through the first TSV C1_T1 but through the second TSV C1_T2. In other words, in FIG. 4, while the first chip C1 basically inputs/outputs the signal through the first channel CH1, if the signal of the first chip C1 cannot be inputted/outputted through the first channel CH1, the signal of the first chip C1 is inputted/outputted through the second channel CH2. For reference, the occurrence of a fail in the channel CH1 including the first TSV C1_T1 means that the signal of the first chip C1 cannot be inputted/outputted through the first TSV C1_T1.

For such an operation, the first chip C1 includes one or more input/output units IO1 and IO2 which are respectively connected to one or more TSVs including the first TSV C1_T1, among the first to fifth TSVs C1_T1 to C1_T5. FIG. 4 shows the case in which the first TSV C1_T1 and the second TSV C1_T2 are respectively connected to the input/output units IO1 and IO2. The input/output units IO1 and IO2 are activated and deactivated in response to repair information R1 of the first chip C1. An activated input/output unit inputs/outputs a signal through a TSV connected to it.

In FIG. 4, while the signal of the first chip C1 is basically inputted/outputted through the first TSV C1_T1 (the first chip C1 performs communication through the first channel CH1), it is inputted/outputted through the second TSV C1_T2 in the case where a fail occurs in the channel CH1 including the first TSV C1_T1. Thus, in the case where no fail occurs in the channel CH1 including the first TSV C1_T1, the input/output unit IO1 is activated and the input/output unit IO2 is deactivated by the repair information R1 of the first chip C1. Conversely, in the case where a fail occurs in the channel CH1 including the first TSV C1_T1, the input/output unit IO1 is deactivated and the input/output unit IO2 is activated by the repair information R1 of the first chip C1. For reference, the repair information R1 of the first chip C1 may be stored in a first information storage unit RS1 included in the first chip C1. The first information storage unit RS1 may include at least one fuse circuit which is determined as to whether to be cut or not, according to the repair information R1 of the first chip C1.

The second chip C2 includes the first to fifth TSVs C2_T1 to C2_T5 and inputs/outputs a signal through the first TSV C2_T1 among the first to fifth TSVs C1_T1 to C1_T5. If a fail occurs in the channel CH2 including the first TSV C2_T1 or the channel CH1 including the first TSV C1_T1 of the first chip C1, the signal of the second chip C2 is inputted/outputted through the second TSV C2_T2. In other words, while the second chip C2 basically inputs/outputs the signal through the second channel CH2, if the signal of the second chip C2 cannot be transferred through the second channel CH1 or if the signal of the first chip C1 cannot be transferred through the first channel CH1, so the first chip C1 transfers the signal through the second channel CH2, the signal of the second chip C2 is inputted/outputted through the third channel CH3. For reference, the occurrence of a fail in the channel CH2 including the first TSV C2_T1 means that the signal of the second chip C2 cannot be inputted/outputted through the first TSV C2_T1.

For such an operation, the second chip C2 includes one or more input/output units IO3 and IO4. The one or more input/output units IO3 and IO4 are respectively connected to one or more TSVs including the first TSV C2_T1 (FIG. 4 shows the case in which the third input/output unit IO3 is connected to the first TSV C2_T1 and the fourth input/output unit IO4 is connected to the second TSV C2_T2), and are activated and deactivated in response to repair information R2 of the second chip C2. In the case where no fail occurs in the first channel CH1 and the second channel CH2, the input/output unit IO3 is activated and the input/output unit IO4 is deactivated by the repair information R2 of the second chip C2. In the case where a fail occurs in the channel CH1 or the second channel CH2, the input/output unit IO3 is deactivated and the input/output unit IO4 is activated by the repair information R2 of the second chip C2. For reference, the repair information R2 of the second chip C2 may be stored in a second information storage unit RS2 included in the second chip C2. The second information storage unit RS2 may include at least one fuse circuit which is determined as to whether to be cut or not, according to the repair information R2 of the second chip C2.

The third chip C3 includes the first to fifth TSVs C3_T1 to C3_T5 and inputs/outputs a signal through the first TSV C3_T1 among the first to fifth TSVs C3_T1 to C3_T5. If a fail occurs in one of the channel CH3 including the first TSV C3_T1, the channel CH1 including the first TSV C1_T1 of the first chip C1 and the channel CH2 including the first TSV C2_T1 of the second chip C2, the signal of the third chip C3 is inputted/outputted through the second TSV C3_T2. In other words, while the third chip C3 basically inputs/outputs the signal through the third channel CH3, if the signal of the third chip C3 cannot be transferred since a fail occurs in one of the first to third channels CH1 to CH3, the signal of the third chip C3 is inputted/outputted through the fourth channel CH4. For reference, the occurrence of a fail in the channel CH3 including the first TSV C3_T1 means that the signal of the third chip C3 cannot be inputted/outputted through the first TSV C3_T1.

For such an operation, the third chip C3 includes one or more input/output units IO5 and IO6. The one or more input/output units IO5 and IO6 are respectively connected to one or more TSVs including the first TSV C3_T1 (FIG. 4 shows the case in which the fifth input/output unit IO5 is connected to the first TSV C3_T1 and the sixth input/output unit IO6 is connected to the second TSV C3_T2), and are activated and deactivated in response to repair information R3 of the third chip C3. In the case where no fail occurs in the first channel CH1, the second channel CH2 and the third channel CH3, the input/output unit IO5 is activated and the input/output unit IO6 is deactivated by the repair information R3 of the third chip C3. In the case where a fail occurs in one of the first to third channels CH1 to CH3, the input/output unit IO5 is deactivated and the input/output unit IO6 is activated by the repair information R3 of the third chip C3. For reference, the repair information R3 of the third chip C3 may be stored in a third information storage unit RS3 included in the third chip C3. The third information storage unit RS3 may include at least one fuse circuit which is determined as to whether to be cut or not, according to the repair information R3 of the third chip C3.

The fourth chip C4 includes the first to fifth TSVs C4_T1 to C4_T5 and inputs/outputs a signal through the first TSV C4_T1 among the first to fifth TSVs C4_T1 to C4_T5. If a fail occurs in one of the channel CH4 including the first TSV C4_T1 and the first to third channels CH1 to CH3 including the first TSVs C1_T1 to C3_T1 of the first to third chips C1 to C3, the signal of the fourth chip C4 is inputted/outputted through the second TSV C4_T2. In other words, while the fourth chip C4 basically inputs/outputs the signal through the fourth channel CH4, if a signal cannot be transferred through one of the first to fourth channels CH1 to CH4, the signal of the fourth chip C5 is inputted/outputted through the fifth channel CH5. For reference, the occurrence of a fail in the channel CH4 including the first TSV C4_T1 means that the signal of the fourth chip C4 cannot be inputted/outputted through the first TSV C4_T1.

For such an operation, the fourth chip C4 includes one or more input/output units IO7 and IO8. The one or more input/output units IO7 and IO8 are respectively connected to one or more TSVs including the first TSV C4_T1 (FIG. 4 shows the case in which the seventh input/output unit IO7 is connected to the first TSV C4_T1 and the eighth input/output unit IO8 is connected to the second TSV C4_T2), and are activated and deactivated in response to repair information R4 of the fourth chip C4. In the case where no fail occurs in the first to fourth channels CH1 to CH4, the input/output unit IO7 is activated and the input/output unit IO8 is deactivated by the repair information R4 of the fourth chip C4. In the case where a fail occurs in one of the first to fourth channels CH1 to CH4, the input/output unit IO7 is deactivated and the input/output unit IO8 is activated by the repair information R4 of the fourth chip C4. For reference, the repair information R4 of the fourth chip C4 may be stored in a fourth information storage unit RS4 included in the fourth chip C4. The fourth information storage unit RS4 may include at least one fuse circuit which is determined as to whether to be cut or not, according to the repair information R4 of the fourth chip C4.

As can be readily seen from the descriptions of the first to fourth chips C1 to C4, in the case where a fail occurs in the first TSV CK_T1 of the K-th chip CK among the first to fourth chips C1 to C4, the K-th to M-th chips CK to C4 among the first to M-th chips C1 to C4 input/output signals through TSVs which are not the first TSVs among the first to N-th TSVs thereof. For example, if a fail occurs in the channel CH4 including the first TSV C4_T1 of the fourth chip C4, only the TSV through which the signal of the fourth chip C4 is to be inputted/outputted is changed to the second TSV C4_T2. However, if a fail occurs in the channel CH3 including the first TSV C3_T1 of the third chip C3, not only the TSV through which the signal of the third chip C3 is to be inputted/outputted is changed to the second TSV C3_T2, but also the TSV through which the signal of the fourth chip C4 is to be inputted/outputted is changed to the second TSV C4_T2. If a fail occurs in the channel CH1 including the first TSV C1_T1 of the first chip C1, the TSVs through which the signals of the first to fourth chips C1 to C4 are to be inputted/outputted are changed from the first TSVs C1_T1 to C4_T1 to the second TSVs C1_T2 to C4_T2. The reason to this is as follows.

One chip (hereinafter, referred to as a “lower chip”) among the first to fourth chips C1 to C4 uses a channel (hereinafter, referred to as a “basic channel”) which is basically used by a chip (hereinafter, referred to as an “upper chip”) adjoining the lower chip and stacked on the lower chip to input/output a signal, as a channel for replacement (hereinafter, referred to as a “replacement channel”) when a fail occurs in the basic channel of the lower chip. That is to say, since the replacement channel of the lower chip and the basic channel of the upper chip are the same, in the case where a fail occurs in the basic channel of the lower chip and repair is carried out using the replacement channel, the upper chip cannot use its basic channel as a matter of course and should be repaired using its replacement channel. For example, the first chip C1 uses the first channel CH1 as the basic channel and uses the second channel CH2 as the replacement channel. The second chip C2 uses the second channel CH2 as the basic channel and uses the third channel CH3 as the replacement channel. Accordingly, in the case where a fail occurs in the second channel CH2, the channel through which the signal of the second chip C2 is to be inputted/outputted may be replaced with the third channel CH3. However, in the case where a fail occurs in the first channel CH1, since the signal of the first chip C1 is inputted/outputted through the second channel CH2 and the signal of the second chip C2 should be inputted/outputted through the third channel CH3, both the channels through which the signals of the first chip C1 and the second chip C2 are inputted/outputted are changed from the basic channels to the replacement channels. If a channel through which the signal of a chip is to be inputted/outputted is repaired, channels through which the signals of all chips stacked thereon are to be inputted/outputted should be repaired.

The repair information R1 to R4 is determined through a test. The repair information R1 to R4 is determined in consideration of whether a chip stacked under a corresponding chip has been repaired or not. For example, the repair information R1 of the first chip C1 is determined according to whether a channel including a TSV of the first chip C1 has failed or not, and the repair information R3 of the third chip C3 is determined according to whether channels including TSVs of the first to third chips C1 to C3 have failed or not.

Here, a range for selecting a TSV through which the signal of a chip is to be inputted/outputted is determined according to the number of TSVs to which input/output units are connected, among the entire TSVs of the chip. Since FIG. 4 shows that input/output units are connected to two TSVs among the TSVs of each chip, a TSV through which the signal of the chip is to be inputted/outputted may be determined as one of the two TSVs. The number of TSVs to which input/output units are connected may be changed according to a design. As the number of TSVs to which input/output units are connected increases, the flexibility of a repair operation may be enhanced.

The interface chip CI includes first to N-th input/output lines IOL1 to IOLN and first to N-th transfer units M1 to MN in order to perform communication (or interfacing) between the outside of the integrated circuit and the first to N-th chips C1 to CN.

The input/output lines IOL1 to IOLN and the transfer units M1 to MN respectively correspond to the first to N-th chips C1 to CN and are component elements for communication of the first to N-th chips C1 to CN corresponding to them. A TSV to and from which the signal of an L-th chip CL is to be inputted/outputted is selected between the TSVs of the first chip C1 by an L-th transfer unit ML corresponding to the L-th chip CL in response to the repair information RL of the L-th chip CL. Accordingly, the TSV of the first chip C1, which is selected by the L-th transfer unit ML corresponding to the L-th chip CL in response to the repair information RL of the L-th chip CL, is a TSV which is electrically connected with a TSV selected among the TSVs of the L-th chip CL in response to the repair information RL of the L-th chip CL. For example, the TSV of the first chip C1 which is selected by the third transfer unit M3 in response to the repair information R3 of the third chip C3 is a TSV which is electrically connected with the TSV selected among the TSVs of the third chip C3 by the repair information R3 of the third chip C3.

Furthermore, in the case where the signal of the second chip C2 is inputted/outputted through the first TSV C2_T1, the second TSV C1_T2 of the first chip C1, which is connected with the first TSV C2_T1 of the second chip C2, is connected with the second input/output line IOL2, and in the case where the signal of the second chip C2 is inputted/outputted through the second TSV C2_T2, the third TSV C1_T3 of the first chip C1, which is connected with the second TSV C2_T2 of the second chip C2, is connected with the second input/output line IOL2. Since a TSV through which the signal of the second chip C2 is to be inputted/outputted is determined by the repair information R2 of the second chip C2, the second transfer unit M2 connects the TSV of the first chip C2 determined in response to the repair information R2 of the second chip C2 with the second input/output line IOL2.

As described above, the flexibility of the repair operation may be determined by the number of TSVs among the TSVs of each chip to which input/output units are connected. While FIG. 4 shows the case in which input/output units are connected to two of the TSVs of each chip, this may be changed according to a design. In the case where input/output units are connected to two TSVs as shown in FIGS. 3 and 4, repair becomes impossible when fails occur in at least two channels.

For example, in FIG. 4, in the case where fails occur in the first channel CH1 and the fourth channel CH4, while the first chip C1 may perform communication using the second channel CH2 and the second chip C2 may perform communication using the third channel CH3, since the third chip C3 cannot use both the third channel CH3 and the fourth channel CH4, it is impossible to repair the integrated circuit. In this case, in the event that three channels are allowed to be selected as communication paths in each chip (that is, input/output units are connected to three TSVs among the TSVs of each chip to be activated in response to repair information), repair becomes possible. In this case, the repair information R1 to R4 of the respective chips may be digital signals of at least two bits.

Table 1 shows how TSVs for inputting/outputting signals of the respective chips are selected according to occurrence of a fail in the integrated circuit shown in FIG. 4.

TABLE 1

| | TSV for inputting/outputting signal of chip | | | | |
|---|---|---|---|---|---|
| First chip (C1) | C1_T1 | C1_T2 | C1_T1 | C1_T1 | C1_T1 |
| Second chip (C2) | C2_T1 | C2_T2 | C2_T2 | C2_T1 | C2_T1 |
| Third chip (C3) | C3_T1 | C3_T2 | C3_T2 | C3_T2 | C3_T1 |
| Fourth chip (C4) | C4_T1 | C4_T2 | C4_T2 | C4_T2 | C4_T2 |
| Failed channel | None | First | Second | Third | Fourth |
| | | channel | channel | channel | channel |
| | | (CH1) | (CH2) | (CH3) | (CH4) |

At least one TSV among the first to N-th TSVs included in each of the first to M-th chips C1 to C4 may be a redundancy TSV which is added for repair. An input/output unit connected to such a redundancy TSV may be a redundancy input/output unit. For example, in the case of the integrated circuit shown in FIG. 4, among the first to fifth TSVs C1_T1 to C1_T5, C2_T1 to C2_T5, C3_T1 to C3_T5, and C4_T1 to C4_T5 included in the first to fourth chips C1 to C4, the second TSVs C1_T2 to C4_T2 may be redundancy TSVs for repair of the integrated circuit, and the input/output units IO2, IO4, IO6, and IO8 connected to the second TSVs C1_T2 to C4_T2 may be redundancy input/output units.

Hereinbelow, a repair sequence of the integrated circuit in accordance with the embodiment of the present invention will be described with reference to FIG. 4 and Table 1.

As described above, the first to fourth chips C1 to C4 basically input/output signals through the first TSVs C1_T1 to C4_T1. In the case where a fail occurs in the channels including the first TSVs C1_T1 to C4_T1 and the signals cannot be inputted/outputted through the first TSVs C1_T1 to C4_T1, the first to fourth chips C1 to C4 input/output the signals through the second TSVs C1_T2 to C4_T2.

To this end, first, a test is performed through the input/output units IO1, IO3, IO5, and IO7 connected to the first TSVs C1_T1 to C4_T1 of the first to fourth chips C1 to C4 to check if a fail occurs in the channels including the first TSVs C1_T to C4_T1 of the first to fourth chips C1 to C4. Next, a test is performed through the input/output units IO2, IO4, IO6, and IO8 connected to the second TSVs C1_T2 to C4_T2 of the first to fourth chips C1 to C4 to check if a fail occurs in the channels including the second TSVs C1_T2 to C4_T2 of the first to fourth chips C1 to C4.

When the tests are completed, a state of the integrated circuit is determined from test results using Table 1, and repair information is generated and stored in the information storage units RS1 to RS4 of the respective chips such that the first to fourth chips C1 to C4 may input/output signals through channels which are free from a fail. After repair is completed, the operation of the integrated circuit becomes the same as described above with reference to FIG. 4.

As is apparent from the above descriptions, according to the embodiments of the present invention, an integrated circuit may effectively perform repair when a fail occurs in a through-chip via in a structure in which through-chip vias formed in stacked semiconductor chips are connected in oblique directions with through-chip vias of adjoining semiconductor chips.

While the present invention has been described with respect to the specific embodiments, it will be apparent to those skilled in the art that various changes and modifications may be made without departing from the spirit and scope of the invention as defined in the following claims.

What is claimed is:

1. An integrated circuit comprising:
a second chip stacked on the first chip and having a plurality of through-chip vias which are disposed at positions corresponding to the plurality of through-chip vias of the first chip and each of which is connected with at least one through-chip via of the first chip arranged in an oblique direction, which is not on a straight line extending in a chip stacking direction, among the plurality of through-chip vias of the first chip,
wherein the first chip inputs/outputs a signal through a through-chip via, which is selected by first repair information among the plurality of through-chip vias of the first chip, and the second chip inputs/outputs a signal through a through-chip via, which is selected by second repair information among the plurality of through-chip vias of the second chip.

2. The integrated circuit of claim 1,
wherein the first chip inputs/outputs a signal through a through-chip via disposed at a first position among the plurality of through-chip vias of the first chip, and, if a fail occurs in a channel including the through-chip via disposed at the first position of the first chip, the first chip inputs/outputs a signal through another through-chip via among the plurality of through-chip vias of the first chip other than the through-chip via disposed at the first position,
wherein the second chip inputs/outputs a signal through a through-chip via disposed at a first position among the plurality of through-chip vias of the second chip, and, if a fail occurs in a channel including the through-chip via disposed at the first position of the second chip, the second chip inputs/outputs a signal through another through-chip via among the plurality of through-chip vias of the second chip other than the through-chip via disposed at the first position, and
wherein the first position of the first chip and the first position of the second chip are arranged on a straight line extending in a stacking direction of the second chip.

3. The integrated circuit of claim 2, wherein, in the case where a fail occurs in the channel including the through-chip via of the is first chip disposed at the first position, the second chip inputs/outputs a signal through another through-chip via among the plurality of through-chip vias of the second chip other than the through-chip via disposed at the first position.

4. The integrated circuit of claim 2,
wherein the first chip comprises one or more input/output units which are connected with through-chip vias corresponding to them among the plurality of through-chip vias of the first chip to input/output a signal to/from the first chip and are activated and deactivated in response to the first repair information,
wherein the second chip comprises one or more input/output units which are connected with through-chip vias corresponding to them among the plurality of through-chip vias of the second chip to input/output a signal to/from the second chip and are activated and deactivated in response to the second repair information, and
wherein the through-chip vias of the first chip to which the input/output units of the first chip are connected and the through-chip vias of the second chip to which the input/output units of the second chip are connected are arranged on straight lines extending in directions parallel to the stacking direction of the second chip.

5. The integrated circuit of claim 4, wherein, among the plurality of through-chip vias of the first chip and the plurality of through-chip vias of the second chip, a through-chip via of the first chip and a through-chip via of the second chip which are disposed at corresponding positions are arranged on a straight line extending in the stacking direction of the second chip.

6. The integrated circuit of claim 1, further comprising:
a third chip stacked in a direction opposite to the stacking direction of the second chip when viewed from the first chip,
wherein the third chip comprises:
a first input/output line for transferring a signal to be inputted/outputted between an outside and the first chip;
a second input/output line for transferring a signal to be inputted/outputted between the outside and the second chip;
a first transfer unit configured to transfer a signal between the through-chip via of the first chip selected by the first repair information among the through-chip vias of the first chip and the first input/output line; and
a second transfer unit configured to select a through-chip via of the first chip which is electrically connected with the through-chip via of the second chip selected by the second repair information among the through-chip vias of the second chip, and transfer a signal between the through-chip via of the first chip and the second input/output line.

7. The integrated circuit of claim 1, wherein the first repair information is stored in the first chip, and the second repair information is stored in the second chip.

8. An integrated circuit comprising:
a first chip having first to N-th (N is a natural number) through-chip vias; and
a second chip stacked on the first chip and having first to N-th through-chip vias,
wherein the K-th (K is a natural number satisfying 1≦K≦N) through-chip via of the first chip and the K-th through-chip via of the second chip are arranged on a straight line extending in a chip stacking direction, the K-th through-chip via of the first chip is connected with at least one through-chip via of the second chip among the first to N-th through-chip vias of the second chip, which is not the K-th through-chip via of the second chip, the first chip inputs/outputs a signal through a through-chip via which is selected by first repair information among the first to N-th through-chip vias of the first chip, and the second chip inputs/outputs a signal through a through-chip via which is selected by second repair information among the first to N-th through-chip vias of the second chip.

9. The integrated circuit of claim 8, wherein the first chip inputs/outputs a signal through the L-th (L is a natural number satisfying 1≦L≦N) through-chip via among the first to N-th through-chip vias of the first chip, and, if a fail occurs in a channel including the L-th through-chip via of the first chip, the first chip inputs/outputs a signal through another through-chip via among the first to N-th through-chip vias of the first chip other than the L-th through-chip via, and
wherein the second chip inputs/outputs a signal through the L-th through-chip via among the first to N-th through-chip vias of the second chip, and, if a fail occurs in a channel including the L-th through-chip via of the second chip, the second chip inputs/outputs a signal through another through-chip via among the first to N-th through-chip vias of the second chip other than the L-th through-chip via.

10. The integrated circuit of claim 9, wherein, in the case where a fail occurs in the channel including the L-th through-chip via of the first chip, the second chip inputs/outputs a signal through another through-chip via among the first to N-th through-chip vias of the second chip other than the L-th through-chip via.

11. The integrated circuit of claim 9,
wherein the first chip comprises one or more input/output units which are respectively connected with one or more through-chip vias including the L-th through-chip via among the first to N-th through-chip vias of the first chip to input/output a signal to/from the first chip and are activated and deactivated in response to the first repair information, and
wherein the second chip comprises one or more input/output units which are respectively connected with one or more through-chip vias including the L-th through-chip via among the first to N-th through-chip vias of the second chip to input/output a signal to/from the second chip and are activated and deactivated in response to the second repair information.

12. The integrated circuit of claim 8, further comprising:
a third chip stacked in a direction opposite to the stacking direction of the second chip when viewed from the first chip,
wherein the third chip comprises:
a first input/output line for transferring a signal to be inputted/outputted between an outside and the first chip;
a second input/output line for transferring a signal to be inputted/outputted between the outside and the second chip;
a first transfer unit configured to transfer a signal between the through-chip via of the first chip selected by the first repair information among the through-chip vias of the first chip and the first input/output line; and
a second transfer unit configured to select a through-chip via of the first chip which is electrically connected with the through-chip via of the second chip selected by the second repair information among the through-chip vias of the second chip, and transfer a signal between the through-chip via of the first chip and the second input/output line.

13. An integrated circuit comprising:
first to M-th chips, which are sequentially stacked, and each including first to N-th (N is a natural number) through-chip vias,
wherein the K-th (K is a natural number satisfying 1≦K≦N) through-chip vias respectively included in the first to M-th chips are arranged on a straight line extending in a stacking direction of the first to M-th chips, the K-th through-chip vias respectively included in the first to M-th chips are connected with one or more through-chip vias among the first to N-th through-chip vias included in the adjacently stacked chip, which are not the K-th through-chip vias, and each of the first to M-th chips inputs/outputs a corresponding signal through through-chip via which are selected by corresponding repair information among the corresponding first to N-th through-chip vias.

14. The integrated circuit of claim 13, wherein each of the first to M-th chips inputs/outputs a corresponding signal through the L-th (L is a natural number satisfying 1≦L≦N) through-chip via among the first to N-th through-chip vias, and, if a fail occurs in a channel including the L-th through-chip via, each of the first to M-th chips inputs/outputs the signal through another through-chip via among the first to N-th through-chip vias other than the L-th through-chip via.

15. The integrated circuit of claim 14, wherein, in the case where a fail occurs in a channel including the L-th through-chip via of an X-th chip (X is a natural number satisfying 1≦X≦M) among the first to M-th chips, each of the X-th to M-th chips among the first to M-th chips inputs/outputs a corresponding signal through the through-chip via which are not L-th through-chip vias among the first to N-th through-chip vias.

16. The integrated circuit of claim 13, wherein each of the first to M-th chips comprises one or more input/output units which are respectively connected with one or more through-chip vias including the L-th through-chip via among the first to N-th through-chip vias to input/output a corresponding signal and are activated or deactivated in response to the corresponding repair information.

17. The integrated circuit of claim 13, further comprising:
an interface chip stacked in a direction opposite to the stacking direction of the second to M-th chips when viewed from the first chip,
wherein the interface chip comprises:
first to M-th input/output lines each corresponding to at least one of the first to M-th chips, and each configured to transfer a signal to be inputted/outputted between the corresponding chip and an outside; and
first to M-th transfer units each corresponding to at least one of the first to M-th chips and at least one of the first to M-th input/output lines, and each configured to transfer a signal between a through-chip vias of the first chip selected among the first to N-th through-chip vias of the first chip by the corresponding repair information and an corresponding input/output line among the first to M-th input/output lines.

18. The integrated circuit of claim 13, wherein a through-chip via of the first chip selected by an L-th transfer unit among the second to N-th transfer units is a through-chip via which is electrically connected with a through-chip via selected among the through-chip vias of a chip corresponding to the L-th transfer unit in response to the corresponding repair information for the chip corresponding to the L-th transfer unit.
